(19) United States
(12) Patent Application Publication
(10) Pub. No.: US 2010/0128439 A1
(43) Pub. Date: May 27, 2010

(54) THERMAL MANAGEMENT SYSTEM WITH GRAPHENE-BASED THERMAL INTERFACE MATERIAL

(75) Inventors: Vinayak Tilak, Niskayuna, NY (US); Kaustubh Ravindra Nagarkar, Clifton Park, NY (US); Loucas Tsakalakos, Niskayuna, NY (US); Todd Garrett Wetzel, Niskayuna, NY (US)

Correspondence Address: GENERAL ELECTRIC COMPANY;GLOBAL RESEARCH, ONE RESEARCH CIRCLE, PATENT DOCKET RM. BLDG. K1-4A59, NISKAYUNA, NY, 12309, US

(73) Assignee: GENERAL ELECTRIC COMPANY, SCHENECTADY, NY (US)

(21) Appl. No.: 12/276,498

(22) Filed: Nov. 24, 2008

(51) Int. Cl. H05K 7/20; C09K 5/14

(52) U.S. Cl. 361/709; 252/71

(57) ABSTRACT

A thermal management system includes graphene paper disposed between a heat source and a heat sink to transfer heat therebetween. The graphene paper is oriented such that the individual layers are substantially perpendicular to the plane of the heat source and the plane of the heat sink to maximize heat transfer. The heat source and the heat sink can be any physical structure that emits and absorbs thermal energy, respectively. The graphene paper may be bonded to the heat source and the heat sink using a bonding agent, such as a thermally conductive material, and the like. The graphene paper may be formed in several different configurations, such as a spring structure, and the like.

### BACKGROUND

This invention relates generally to a thermal management system, and more particularly to a thermal management system with a graphene-based thermal interface material in which individual graphene sheets are aligned perpendicular to the plane of microchips and heat spreaders or heat sinks, thus providing a superior thermal conduction path from chip to sink.

Graphene is a novel material that was discovered by a team of scientists at the University of Manchester in 2004. Basically, graphene is a sheet of carbon atoms bound together with double electron bonds (called a sp² bond) in a thin film only one atom thick. Atoms in graphene are arranged in a hexagonal lattice pattern. The carbon-carbon bond length in graphene is approximately 1.42 Angstrom.

Graphene is the basic structural element of all other graphitic materials including graphite, carbon nanotubes and fullerenes. For example, when graphene is rolled a ball, a carbon buckyball is formed. When graphene is rolled into a tube, a carbon nanotube (CNT) is formed. Buckypaper is a thin sheet made from an aggregate of carbon nanotubes, or “buckytubes.” When graphene is stacked at least ten layers high, graphene transforms into bulk graphite. Graphene can also be considered as a large aromatic molecule, the limiting case of the family of flat polycyclic aromatic hydrocarbons called graphenes.

By stacking more and more graphene layers on top of each other, the material's properties change dramatically. A single layer of graphene exhibits quantum staircase in Hall conductivity and ballistic transport: charge carriers in the single layer can travel thousands of inter-atomic distances without scattering. At two layers thick, graphene is still a zero-gap semiconductor exhibiting the quantum Hall effect. But, unlike single-layer graphene, double-layer graphene lacks a first step in the quantum staircase. For three or more graphene layers, however, the electronic properties begin to diverge, ultimately approaching the 3D limit of bulk graphene at about ten layers in thickness. Thus, graphene stacked ten layers or thicker should probably not be called graphene; it is more accurately referred to as a thick film of graphite.

The near-room temperature ‘in-plane’ thermal conductivity of a single sheet of graphene was recently measured to be between (4.84±0.44)×10³ to (5.30±0.48)×10³ W/mK. These measurements, made by a non-contact optical technique, are in excess of those measured for carbon nanotubes or diamond. It can be shown by using the Wiedemann-Franz law, that the thermal conduction is phonon-dominated. However, for a gated graphene strip, an applied gate bias causing a Fermi Energy shift much larger than k_{B}T can cause the electronic contribution to increase and dominate over the phonon contribution at low temperatures.

Potential for this high conductivity can be seen by considering graphite, a 3D version of graphene that has basal plane thermal conductivity of over a 1000 W/mK (comparable to diamond). In graphite, the c-axis (out of plane) thermal conductivity is over a factor of ˜100 smaller due to the weak binding forces between basal planes as well as the larger lattice spacing. In addition, the ballistic thermal conductance of a graphene is shown to give the lower limit of the ballistic thermal conductances, per unit circumference, length of carbon nanotubes.

All electronic circuits are limited by the amount of heat dissipated, which is a surrogate for the maximum juncture temperature of a chip is allowed to experience. In the full thermal resistance path from the chip to the ultimate sink, often the thermal interface material (TIM) is the limiting resistance. Any improvement in TIM thermal conductivity will have major implications on power density and reliability of electronic circuits in a wide range of applications.

Most existing thermal interface materials (TIMs) are based on greases, silicones, and epoxies, which all have very poor thermal conductivity (<20 W/mK). In the past, attempts have been made to mix high thermal conductivity fillers to improve TIM conductivity, but they have had minimal success because the particles in the fillers are too small to span the gap from the chip to the heat sink. Therefore, the effective conductivity is still mostly dictated by the low conductivity matrix, and there is a need to improve the thermal conductivity of the thermal interface material, especially in applications involving electronic circuits.

### SUMMARY OF THE INVENTION

Briefly, a thermal interface material comprises a plurality of sheets of graphene bonded together using hydrogen or covalent bonding to form graphene paper. The graphene paper is interposed between a heat source and a heat sink to transfer heat between the heat source and the heat sink.

In another aspect, a thermal management system comprises a heat source; a heat sink; and a thermal interface material comprising a plurality of sheets of graphene bonded together using hydrogen or covalent bonding to form graphene paper. The graphene paper is interposed between the heat source and the heat sink to transfer heat between the heat source and the heat sink.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 is an image from a scanning electron microscope (SEM) of graphene oxide paper having a thickness of about 10 μm.

FIG. 2 is a schematic view of a thermal management system that includes substantially parallel rows of graphene paper disposed between a heat source and a heat sink.

FIG. 3 is a schematic view of a thermal management system that includes graphene paper folded into a U-shaped configuration and disposed between the heat source and the heat sink.

FIG. 4 is a schematic view of a thermal management system that includes graphene paper wrapped around and in direct contact with the heat source, for example, a printed circuit board (PCB) and the heat sink.

FIG. 5 is a schematic view of a thermal management system that includes graphene paper in the form of an S-shaped spring structure disposed between the heat source, for example, a printed circuit board (PCB) and the heat sink.

FIG. 6 is a schematic view of a thermal management system that includes graphene paper in the form of a U-shaped spring structure disposed between the heat source, for example, a printed circuit board (PCB) and the heat sink.

FIG. 7 is a schematic view of a thermal management system that includes graphene paper in the form of a coil disposed between the heat source, for example, a printed circuit board (PCB) and the heat sink.

FIG. 8 is a schematic view of another embodiment of a thermal management system in which individual sheets of graphene paper are disposed between a printed circuit board (PCB) and the heat sink to create thermal transport/phonon paths on the PCB;

FIG. 9 is a schematic view of an alternate embodiment of the system of FIG. 8 with the addition of a patterned graphene phonon transport traces stacked on the outer surface of the PCB.

FIG. 10 is a schematic view of a thermal management system including sheets of graphene paper wrapped around multiple stacked die and a printed circuit board (PCB) and connected to a heat sink on an opposite side of the PCB to remove heat from each individual stacking die in accordance with an alternate embodiment of the invention.

FIG. 11 is a schematic view of a test apparatus for measuring the thermal diffusivity of graphene paper.

FIG. 12 is a graph of the test data for the measurement of the thermal conductivity of graphene paper having a thickness of 0.014 mm in accordance with the invention.

### DETAILED DESCRIPTION

Graphite oxide is a layered material consisting of hydrophilic oxygenated graphene sheets (graphene oxide sheets) bearing oxygen function groups on their basal planes and edges. Recently, it has been shown by researchers at the University of Minnesota that graphite oxide can undergo complete exfoliation in water, yielding colloidal suspensions of almost entirely individual graphene oxide sheets with a mean lateral dimension of approximately 1 μm. Such sheets can be chemically functionalized, dispersed in polymer matrices, and deoxygenated to yield novel composites. As used herein, graphene paper and graphene oxide paper are synonymous with each other with the only difference being that the oxide in graphene oxide paper is reduced using hydrazene before the individual sheets are stacked together as graphene paper.

It also has been recently shown by researchers at the University of Texas at Austin that these graphene oxide sheets can be assembled into a paper-like material under a directional flow, similar to the way buckypaper is formed from carbon nanotubes. The graphene oxide paper was made by filtration of colloidal dispersions of graphene oxide sheets through an Anodisc™ inorganic membrane filter that is fabricated from a unique form of aluminum oxide with a highly controlled, uniform capillary pore structure. The graphene oxide sheets were then air dried and peeled from the filter. The thickness of each graphene oxide paper sample was controlled by adjusting the volume of the colloidal suspension. The thickness of the free-standing graphene oxide paper ranged between about 1 μm to about 30 μm. Referring now to FIG. 1, an image taken by a scanning electron microscope (SEM) shows well-packed layers through almost the entire cross-section of a sample of graphene oxide paper having a thickness of approximately 10 μm.

It should be appreciated that graphene paper is different from buckypaper for thermal heat spreading applications for several reasons. One reason is that graphene paper has significant overlap of the individual graphene platelets as compared to buckypaper in which the individual tubes typically form a matrix with the overlap area between individual tubes being significantly smaller than the overlap area between graphene sheets. This overlap results in lower thermal resistance between individual graphene sheets and therefore better heat transport. The thermal resistance at the overlap region of nanotubes is the biggest contributor to the thermal resistance in buckypaper. Graphene paper therefore has a significant advantage to buckypaper. Another reason is that the stacking order of the individual sheets of graphene paper, which gives the graphene paper superior thermal conductivity, is not possible in buckypaper because carbon nanotubes, being 1-D structures cannot be stacked like graphene, which are 2-D structures. Yet another reason is that inter-lamellar water present between individual sheets of graphene paper, which provides graphene paper with superior thermal conductivity, is not present in buckypaper. The combination of these reasons makes the graphene paper a superior thermal conductor than buckypaper.

Given that inter-lamellar water is present between individual sheets of graphene paper, the individual sheets are held together by hydrogen or covalent bonding. By contrast, the individual sheets in commercially available graphite paper are held together by Van der Walls bonding. The inventors of the present application realized this distinction between graphene oxide paper and graphite paper, and determined that graphene paper may exhibit superior mechanical properties, and in particular superior thermal conductivity properties, as compared to commercially available graphite paper. Specifically, the inventors realized that the hydrogen or covalent bonding of the individual sheets in graphene paper would decrease phonon scattering, and therefore increase the thermal conductivity of the graphene paper.

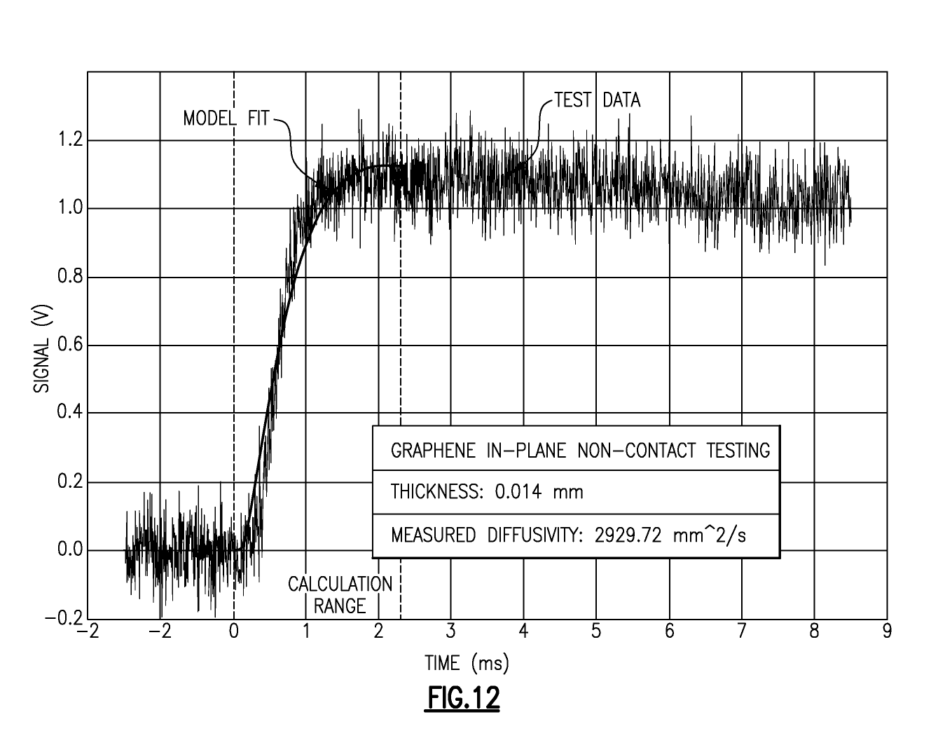

Studies were conducted by the inventors to measure the thermal diffusivity of graphene paper having a thickness of about 14 μm (0.014 mm) using a laser flash technique apparatus 100 shown in FIG. 10. The apparatus 100 includes a light source 102 that emits electromagnetic energy (indicated by the arrows) through a first mask 104 that strikes one side of the graphene paper 106. The graphene paper 106 absorbed the electromagnetic energy and is heated. The infrared energy (indicated by the arrows) emitted by the graphene paper 106 passes through a second mask 108 located on the opposite side of the graphene paper 106. The infrared energy is detected by an infrared detector 110, which measures the rate of increase in the temperature of the graphene paper 106, which was plotted as a voltage signal and compared against well-established models to measure the thermal diffusivity. As shown in FIG. 11, the thermal diffusivity of the graphene paper 106 was measured to be about 30 cm²/s (2929.72 mm²/s).

The density and specific heat of the graphene paper 106 were also measured by the inventors. The specific heat was measured to be about 0.8 J/gK using a differential scanning calorimetric technique. The density was measured to be about 1.83 g/cc using He Pycnometry. Subsequently, the thermal conductivity of the graphene paper 106 was calculated to be about 44 W/cmK.

Based on the measurements of the thermal conductivity by the inventors, it was envisioned that individual sheets of the graphene paper could be aligned to be perpendicular to the plane of a heat source and heat spreader or heat sinks, thus providing a superior conduction path from the heat source to the heat sink.

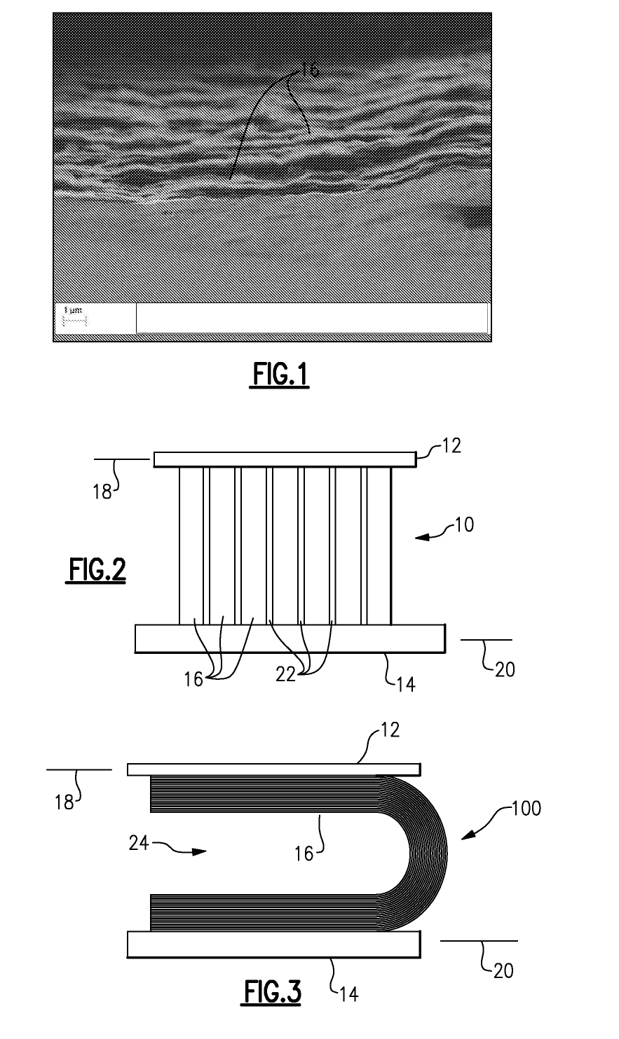

Referring now to FIG. 2, a schematic diagram of a thermal management system 10 according to an embodiment using the principles of the invention is shown. The system 10 includes a heat source 12, a heat spreader or heat sink 14, and graphene paper 16 disposed between the heat source 12 and the heat sink 14. It will be understood that the heat source 12 can be any physical structure or component that emits thermal energy to its environment, and that the heat sink 14 can be any physical structure that absorbs thermal energy. All the different physical structure in which the invention can be used are too numerous to mention here. Some examples of the heat source 12 and the heat sink 14 include, but are not limited to, computer servers, avionic systems, computer components, medical imaging systems (CT, ultrasound, x-ray, MRI, and the like), and energy conversion devices, such as thermoelectric generators, photovoltaic (solar) cells, and the like.

The graphene paper 16 is arranged such that individual sheets are aligned substantially perpendicular to the planes 18, 20 of the heat source 12 and the heat sink 14, thereby providing a superior thermal conduction path between the heat source 12 and the heat sink 14. In one embodiment, the graphene paper 16 may have a thickness in a range between about 10 μm to about 200 μm. It is noted that in the illustrated embodiment, the plane 18 of the heat source 12 is substantially parallel to the plane 20 of the heat sink 14. The individual sheets of graphene paper 16 can be bonded together by using a bonding agent 22. In some embodiments, the bonding agent 22 comprises a thermally conductive material, such as a liquid metal (for example, gallium, indium, or alloys of these metals), graphite, copper, gold, silver, thermal cement, thermal epoxy, and the like. In some embodiments, the bonding agent 22 comprises solders, such as Au—Sn, and the like.

The graphene particles can be oriented substantially perpendicular to the heat source 12 and the heat sink 14 using a variety of different methods. One method is to stack and bond layers of the graphene paper 16 into blocks, and then slice the blocks into thin layers perpendicular to the orientation of the graphene sheets, thus resulting in blocks or sheets with graphene particles in a perpendicular orientation. Another method is to take a sheet of graphene paper, fan-folding it on itself to make a block of graphene, and then slicing the block to make sheets or blocks with graphene particles in a perpendicular orientation.

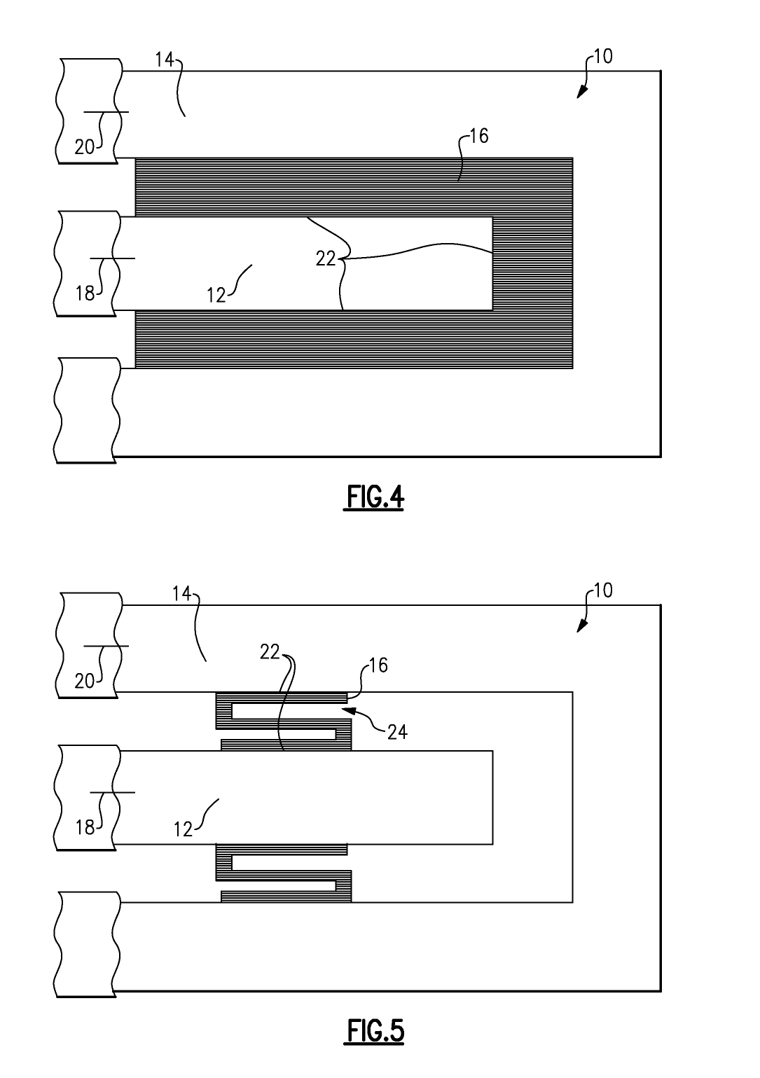

Referring now to FIG. 3, a schematic diagram of a system 10 according to another embodiment using the principles of the invention is shown. The system 100 includes the heat source 12, the heat spreader or heat sink 14, and graphene paper 16 disposed between the heat source 12 and the heat sink 14. In this embodiment, the graphene paper 16 is folded to form a generally U-shaped configuration having a gap 24 between layers of the graphene paper 16. The graphene paper 16 is bonded to the heat source 12 and the heat sink 14 using a bonding agent 22, which in particular embodiments comprises a thermally conductive material, such as a liquid metal (for example, gallium, indium, or alloys of these metals), graphite, copper, gold, silver, thermal cement, thermal epoxy, and the like. In some embodiments, the bonding agent 22 comprises solders, such as Au—Sn, and the like. Similar to the system 10, the graphene paper 16 of the system 100 is arranged such that individual particles are aligned substantially perpendicular to the planes 18, 20 of the heat source 12 and the heat sink 14, thereby providing a superior thermal conduction path between the heat source 12 and the heat sink 14.

Typically, a conventional electronic system, such as a server, local exchange, and the like, includes electronic components and/or subsystems of components that are mounted to printed wiring boards or printed circuit boards. One or more printed wiring boards are often assembled together within a card shell or pack (also referred to in the art as circuit cards, chassis, cases or “packs”) that is sized and shaped for mounting within a rack housing. A typical card shell or pack includes a thermal management system that includes one or more cooling assemblies having a thermal saddle heat sink, one or more heat pipes, and a thermal connector. Each thermal saddle is positioned adjacent an active, heat generating electronic component, such as a processor chip, voltage regulator, power chip, and the like, to conductively receive operating heat during operation of the electronic system. A conventional thermal management system is described, for example, in U.S. Pat. No. 6,804,117.

Another conventional thermal management system uses a wedgelock system that uses conduction to cool one or more T/RIMM modules and power supplies, as described in U.S. Pat. No. 6,615,997.

Referring now to FIGS. 4-10, one embodiment of the invention results from replacing the thermally conductive material(s) used in the conventional electronic systems described above with the graphene paper 16 of the invention. This can be accomplished in many different configurations. For example, as shown in FIG. 4, the heat source 12 comprises a printed wiring board or a printed circuit board (PCB). The graphene paper 16 is wrapped or disposed between the heat source 12 and the heat sink 14 such that the graphene particles are substantially perpendicular to the planes 18, 20 of the heat source 12 and the heat sink 14. The graphene paper 16 may be bonded to the heat source 12 and the heat sink 14 using the bonding agent 22, which, as above, may comprise a thermally conductive material, such as a liquid metal (for example, gallium, indium, or alloys of these metals), graphite, copper, gold, silver, thermal cement, thermal epoxy, and the like. In some embodiments, the bonding agent 22 comprises solders, such as Au—Sn, and the like.

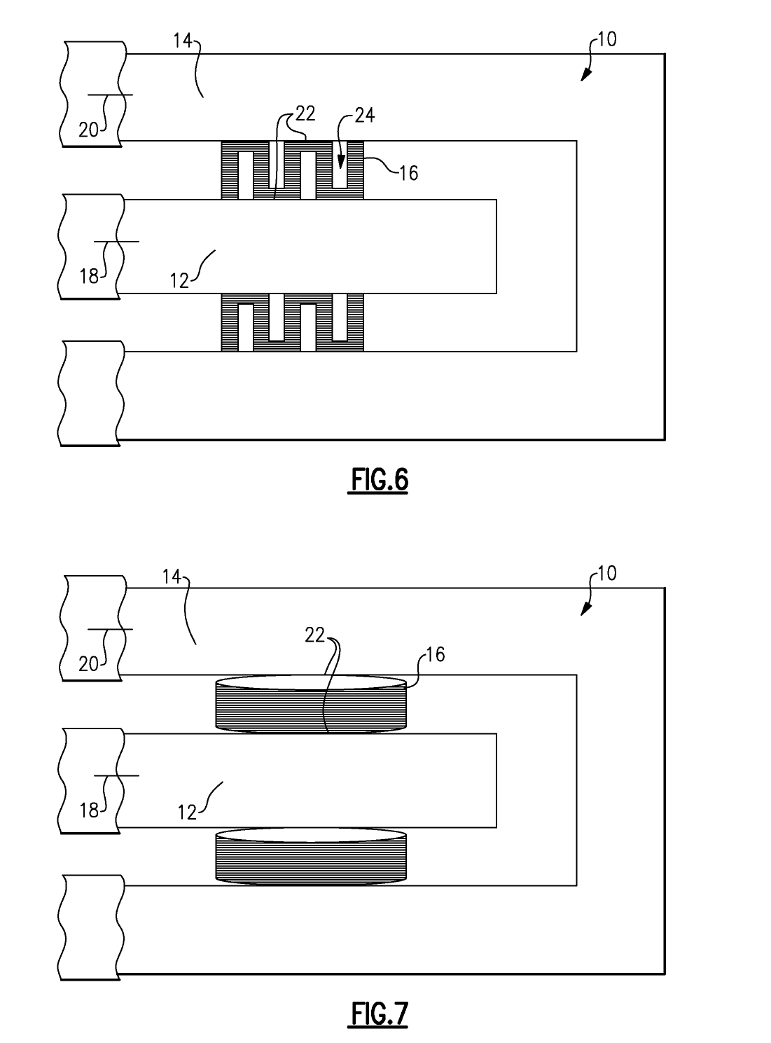

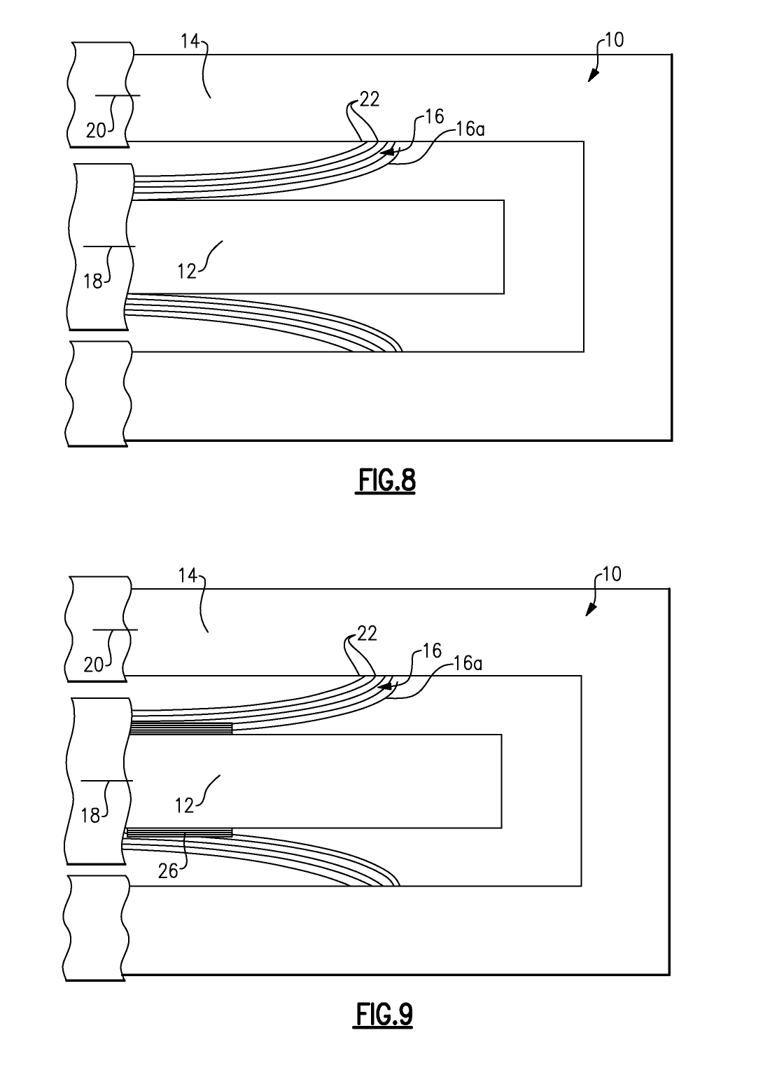

The graphene paper 16 can be disposed between the heat source 12, for example, the PCB and the heat sink 14 in many different configurations. For example, FIG. 5 shows an alternate embodiment of the thermal management system 10 that includes graphene paper 16 in the form of a U-shaped spring structure disposed between the heat source 12, for example, a printed circuit board (PCB) and the heat sink 14. In another example, FIG. 6 shows another embodiment FIG. 6 of the thermal management system 10 that includes graphene paper 16 in the form of a U-shaped spring structure disposed between the heat source 12, for example, a printed circuit board (PCB) and the heat sink 14. In the embodiments shown in FIGS. 5 and 6, the graphene paper 16 may be press fit between the heat source 12 and the heat sink 14, rather than bonded with the thermally conductive material 22. In yet another example, FIG. 7 shows another alternate embodiment in which the graphene paper 16 is shaped in the form of a coil.

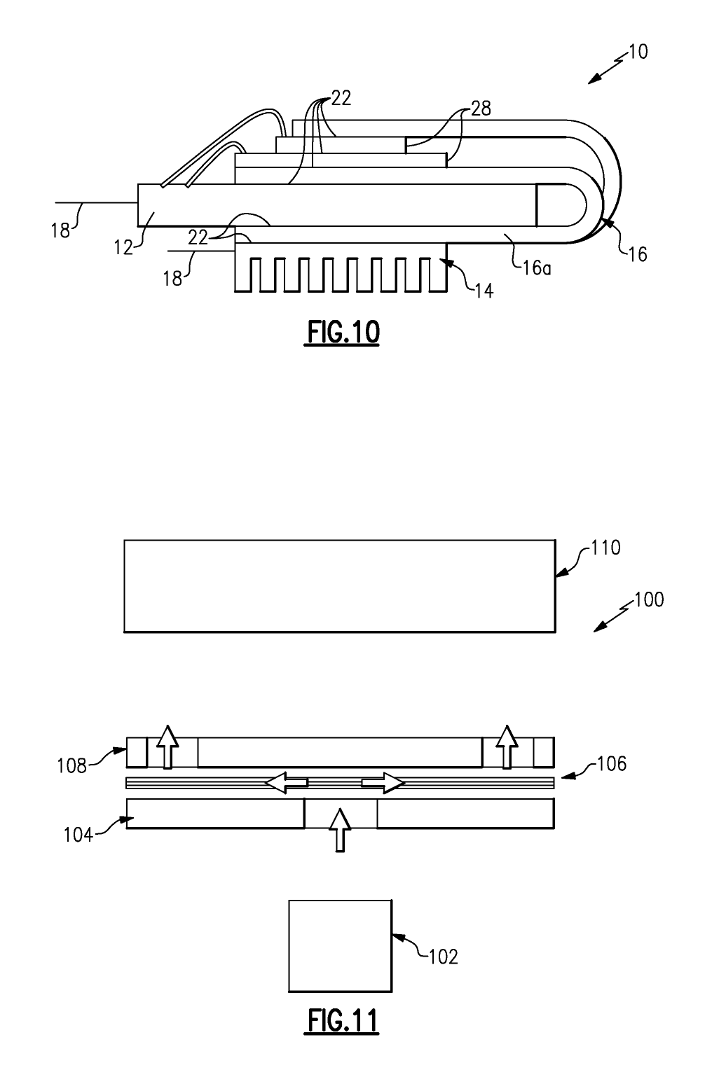

FIG. 8 shows an embodiment of the invention in which individual sheets 16a of the graphene paper 16 are disposed between the heat source 12, for example, a PCB, and the heat sink 14 to create thermal transport/phonon paths on the PCB 12. FIG. 9 shows an alternate embodiment similar to the embodiment of FIG. 8 with the addition of a patterned graphene phonon transport traces 26 stacked on the outer surface of the PCB 12.

FIG. 10 shows an embodiment of the invention in which individual sheets 16a of graphene paper 16 wrapped around multiple stacked die 28 and the heat source 12, for example, a PCB, and connected to the heat sink 14 on an opposite side of the PCB 12 to remove heat from each individual die 28.

As described above, the thermal interface material comprising a plurality of sheets of graphene paper bonded together using a bonding agent has superior thermal conductivity as compared to conventional thermal interface materials. The thermal interface material of the invention can be used in a variety of different application, which are too numerous to mention here. Some examples include, but are not limited to, radiators and coatings therein; heat sink coatings for computers and electronics in general; heat exchanger coatings for gas/steam turbines; conformal coatings on a chip or device for removing heat from regions of high current or areas of peak field; conformal coatings on an RF device, power device, and the like; conformal coatings on high power LEDs, lasers, and the like; coatings on power overlay modules; large area coatings for high thermal uniformity on reactor susceptors, for example, MOCVD, MBE systems; and large area coatings for high thermal uniformity around engines to avoid housing and shell cracking.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A thermal interface material comprising a plurality of sheets of graphene paper bonded together using a bonding agent, wherein the plurality of sheets are oriented substantially parallel to each other.

2. The material of claim 1, wherein the graphene paper is interposed between a heat source and a heat sink to transfer heat between the heat source and the heat sink.

3. The material of claim 2, wherein the plurality of sheets of graphene paper is oriented substantially perpendicular to a plane of the heat source and a plane of the heat sink.

4. The material of claim 2, the bonding agent comprises a thermally conductive material for bonding the graphene paper to the heat source and the heat sink.

5. The material of claim 4, wherein the bonding agent comprises a thermally conductive material selected from the group consisting of graphite, copper, gold, silver, gallium, indium, thermal cement, and thermal epoxy.

6. A thermal management system, comprising:
a heat source;
a heat sink; and
a thermal interface material comprising a plurality of sheets of graphene bonded together using hydrogen or covalent bonding to form graphene paper, the graphene paper interposed between the heat source and the heat sink to transfer heat between the heat source and the heat sink.

7. The system of claim 6, wherein the plurality of sheets of graphene paper is oriented substantially perpendicular to a plane of the heat source and a plane of the heat sink.

8. The system of claim 6, further comprising a bonding agent for bonding the graphene paper to the heat source and the heat sink.

9. The system of claim 8, wherein the bonding agent comprises a thermally conductive material selected from the group consisting of graphite, copper, gold, silver, gallium, indium, thermal cement, and thermal epoxy.

10. The system of claim 6, wherein the heat source comprises an electronic circuit board, a solar cell, or a thermoelectric element.
